(19) United States
(12) Patent Application Publication
(10) Pub. No.: US 2002/0122304 A1
(43) Pub. Date: Sep. 5, 2002

(54) Printed circuit board ejector system with improved EMI shielding

(75) Inventor: Lorraine I. Duncan, Taunton, MA (US)

Correspondence Address: KUDIRKA & JOBSE, LLP, ONE STATE STREET, SUITE 1510, BOSTON, MA, 02109, US

(73) Assignee: Cereva Networks, Inc., Marlborough, MA

(21) Appl. No.: 10/026,864

(22) Filed: Dec. 21, 2001

Related U.S. Application Data
(60) Provisional application No. 60/258,001, filed on Dec. 22, 2000.

(51) Int. Cl. H05K 9/00

(52) U.S. Cl. 361/818

(57) ABSTRACT

In a printed circuit board ejector system, ejector levers are mounted on the outer surface of a faceplate that is constructed to withstand printed circuit board insertion forces without bending or breaking. The faceplate is then fastened to the printed circuit board. Since there is no opening in the faceplate through which the ejector lever passes, electromagnetic radiation cannot leak through the faceplate at this location.

### RELATED APPLICATIONS

This application is related to, and claims priority of, U.S. provisional application serial No. 60/258,001, entitled PRINTED CIRCUIT BOARD EJECTOR SYSTEM WITH IMPROVED EMI SHIELDING, filed Dec. 22, 2000 by Lorraine I. Duncan.

### FIELD OF THE INVENTION

This invention relates to apparatus that shields electromagnetic radiation emitted from printed circuit boards.

### BACKGROUND OF THE INVENTION

The density with which electronic circuitry can be integrated has been increasing dramatically for decades. As a consequence, the clock frequency at which electronic circuitry is operated has been increasing correspondingly and with it the problem of electromagnetic radiation emanating from the printed circuit boards (PCBs) used to interconnect that circuitry. Shielding to reduce electromagnetic interference (EMI) generated by such circuitry must be effective at least up to the fifth harmonic of the clock frequency to meet radiation emission restrictions imposed by national and international standards. Thus, the shielding for circuitry operating at 2.5 GHz must be effective up to at least 12.5 GHz. At such frequencies, an aperture as small as 0.25 inches can be an effective antenna.

Another consequence of the increased density of electronic circuitry is the increased number of pins needed to connect PCBs to backplanes resulting in an increase in the force needed to mate the PCB and backplane connectors. It is common for well over 100 lbs. of insertion force to be required to make the connection. This necessitates the use of PCB injectors, that is, levers attached to the PCB that can engage the card cage into which the PCB is to be inserted, thereby providing a mechanical advantage which forces the board into the connectors. Since the same lever is generally used to aid in the ejection of the board, they are often referred to as ejectors, even when both functions are intended; that convention is used in the present disclosure.

For EMI shielding purposes, PCBs are typically provided with a thin metal faceplate, mounted at the front of the board and perpendicular to it so that when a set of boards are inserted into a card cage, the PCB faceplates extend across the spaces between the boards and provide a nearly continuous metal shield across the front of the card cage. However, all prior art card PCB ejectors require a relatively large slot to be cut through the metal faceplate so that they can be attached directly to the printed circuit board. This direct attachment is necessary to provide the mechanical strength needed to withstand the required insertion force. Unfortunately, it is difficult if not impossible to keep the dimensions of these slots smaller than 0.25 in. and still accommodate levers of the size needed to provide the required mechanical advantage. Furthermore, again to withstand the required insertion force, the ejectors usually have to be made of metal. Consequently, the current flowing around the slot induces a high-frequency current in the metal ejector itself, which thereby becomes an effective radiator of the energy transferred to it. As the length of the ejector is increased to support greater insertion forces, it becomes an even more effective antenna at the frequencies of concern. As a result, prior art ejectors make it very difficult for high-speed electronic products to be compliant with emissions standards.

### SUMMARY OF THE INVENTION

In accordance with the principles of the present invention, ejector levers are mounted on the outer surface of a electrically-conductive PCB faceplate that is constructed to withstand the required insertion forces without bending or breaking. The faceplate is then fastened to the PCB. Since there is no opening in the faceplate through which the ejector lever passes, electromagnetic radiation cannot leak through the faceplate at this location.

When the PCB and ejector assembly is inserted into a card cage, the ejector levers engage the card cage in order to provide the force necessary to insert and the PCB and seat its connectors and to remove the PCB.

In one embodiment, the ejector levers are mounted on the faceplate surface by means of bolts that pass through the faceplate.

### BRIEF DESCRIPTION OF THE DRAWINGS

The above and further advantages of the invention may be better understood by referring to the following description in conjunction with the accompanying drawings in which:

FIG. 1 is a perspective view of a printed circuit board incorporating the ejector according to the present invention.

FIG. 2A is an enlarged perspective view showing the ejector lever, the faceplate and the manner of mounting the faceplate on the printed circuit board.

FIG. 2B is a cross-section of one embodiment of a faceplate.

FIG. 3 is an exploded view of the faceplate and ejector levers.

### DETAILED DESCRIPTION

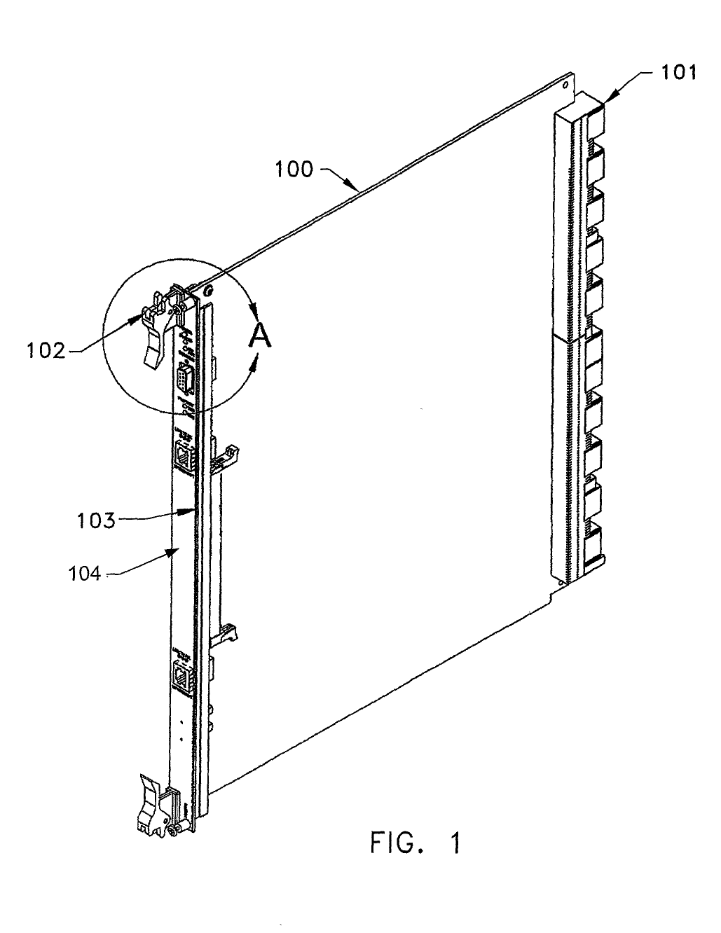

A typical PCB assembly with an ejector constructed in accordance with the principles of the invention is shown in FIG. 1. The PCB itself 100 carries the electronic circuitry that communicates with a back plane (not shown) through one or more high-density connectors 101. The ejector assembly comprises an electrically-conductive faceplate 103 that is fastened to the front edge of the PCB assembly 100, both to provide a carrier for front-side connectors, displays and handles and to contain the electromagnetic radiation that is generated by the circuitry on the board. As with prior art designs, faceplate 103 has a sufficient width to extend across the spaces between adjacent printed circuit boards when the boards are mounted in a conventional card cage.

In accordance with the principles of the invention, this faceplate 103 is much heavier in construction than the prior art faceplates used only for shielding purposes. In particular, the faceplate 103 is constructed to withstand the forces required for insertion and removal of the PCB into and from the card cage without bending or breaking. For example, in one embodiment, faceplate 103 can be constructed from metal with a heavy thickness. Alternatively, stiffeners or ribs can be added to prevent bending and breaking as discussed below.

Since the high-density connectors 101 require significant force to be inserted into the mating connectors on the backplane (not shown), the ejector assembly further includes ejectors 102 are attached to the outer surface 104 of the faceplate 103 at the top and the bottom of the outer edge 104 rather than the PCB 100 assembly itself.

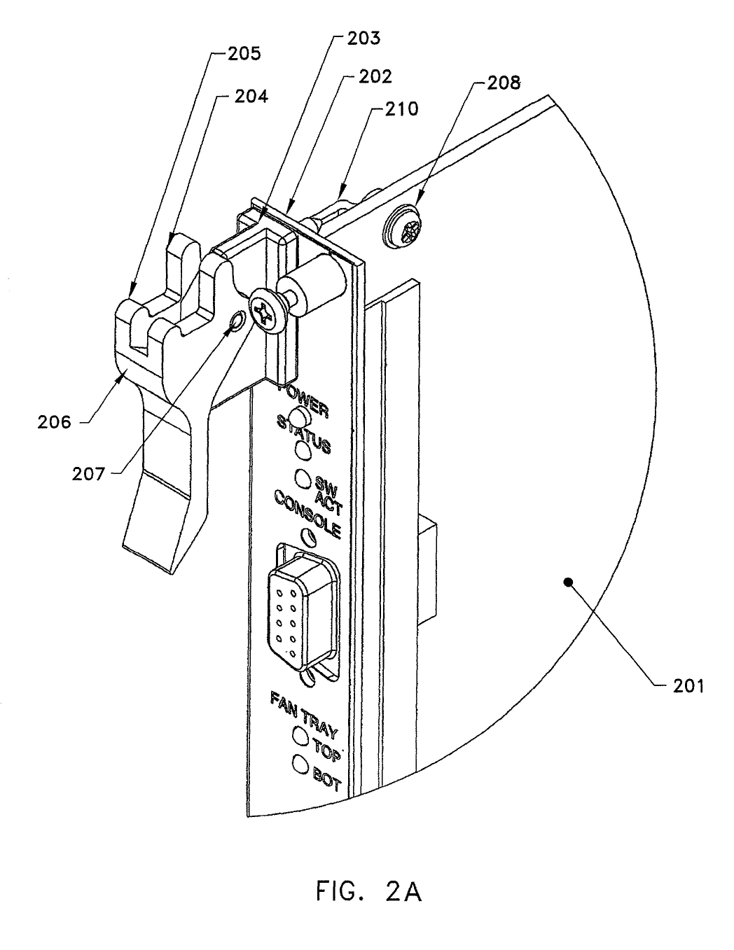

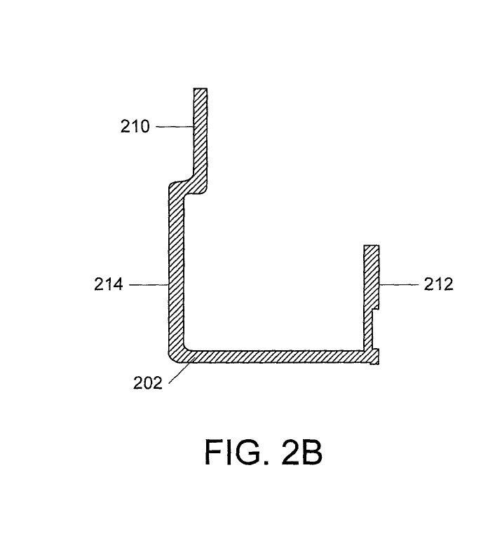

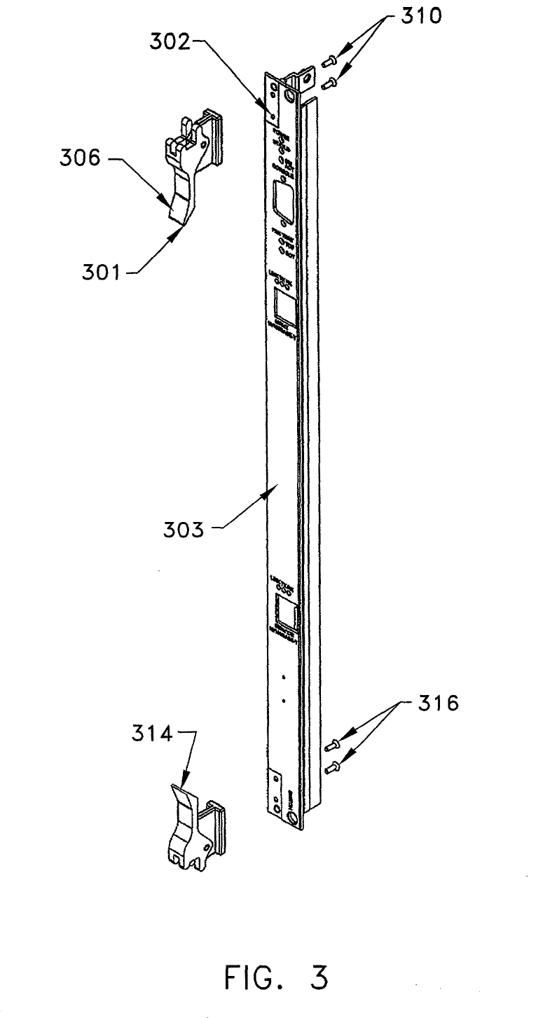

The inventive ejectors 102 are shown in greater detail in FIG. 2A which enlarges the area “A” shown in FIG. 1. As illustrated, the faceplate 202 is fastened to the PCB 201 by means of brackets, of which bracket 210 is shown. Bracket 210 is attached to faceplate 202 by suitable means. For example, bracket 210 may be formed as part of faceplate 202. In one embodiment, a plurality of brackets can be formed as integral legs extending perpendicularly from faceplate 202. In still another embodiment, faceplate 202 can be substantially U-shaped with one leg of the U-shape being fastened to PCB 201. The cross section of such a U-shaped design is shown in FIG. 2B. Here the bracket 210 comprises one leg of the U-shaped faceplate 202. A stiffening rib 212 has also been added as the other leg. A faceplate 202 with the cross section of FIG. 2B is shown in the embodiments depicted in FIGS. 1 and 3. The faceplate shape would typically be made from a heavy gauge metal, for example, 0.040″ thick aluminum by suitable means, such as extrusion. In this embodiment, the bracket portion 210 is offset from the rib 214 that extends from the faceplate 202. This offset brings the bracket 210 within 0.180″ of the force vector applied by the ejector lever, thereby not allowing the faceplate to bend or break. The force vector is also in-line with the neutral axis of the PCB which provides additional support of the faceplate and allows a direct translation of force to the backplane connectors.

Additionally, bracket 210 may be a separate piece that is bolted to the faceplate 202 or attached by welding the bracket to the faceplate 202. Bracket 210 may also be attached by means of a suitable adhesive, such as an epoxy adhesive.

Bracket 210 is also fastened to the PCB 201. In FIG. 2, bracket 210 is fastened to PCB 201 by through-bolts, of which bolt 208 is shown. Although only one bracket is shown, additional brackets (or alternatively a continuous rib) would be used. The brackets or rib form a secure connection to the PCB 201 that can withstand the insertion force required to fully seat the connectors 101. However, other alternative arrangements can be used to fasten the brackets to the PCB 201. For example, the brackets may be formed with two opposing sections. One bracket section can contain pins that pass through holes in the PCB 201 when the bracket sections are assembled. In another arrangement, the PCB 201 may have notches along its edge that are engaged by teeth in the brackets.

Each ejector consists of a lever 206 attached by a hinge 207 to a mounting block 203. The lever 206 is equipped with both an insertion tooth 204 and an extraction tooth 205, the former tooth 204 engaging the inside of a track at the outer edge of the card cage (not shown) when the PCB assembly is inserted and the latter tooth 205 engaging the outside of the same track when the assembly is extracted.

The mounting block 203 is designed to be fastened to the faceplate 202 as shown in FIG. 3, rather than to the PCB 201 as is conventionally done. In one embodiment, the mounting block is bolted to the faceplate 203. In an embodiment in which the bracket 210 is bolted to the faceplate 202, the bolt which is used to attach the bracket 210 to faceplate 202 may pass through a hole in faceplate 202 and thread into mounting block 203 so as to fasten the three parts together. Also, separate bolts can be used to fasten mounting block 203 to faceplate 202 and to fasten bracket 210 to faceplate 202. Alternatively, the mounting block 203 could be fastened to the faceplate 202 by other suitable means, such as welding or by means of an adhesive, such as epoxy adhesive.

As shown in FIG. 3, in an embodiment which the ejector assembly is bolted to the faceplate, screws 312 holding the ejector assembly 301 to the faceplate 303 pass through small holes 302 and fit into threaded holes (not shown) in the back surface of the mounting block 303. Holes 302 are sealed by the mounting screws 312, resulting in extremely low radiation loss, even at very high frequencies. In other embodiments in which the ejector assembly 301 is welded or fastened by adhesive, the faceplate 303 remains continuous thereby also resulting in extremely low radiation loss.

A second ejector assembly 314 is attached to the faceplate 303 also by means of two screws 316. In the specific example shown, only two holes 302, each 0.090 in. in diameter, are required to attach an ejector 301 capable of exerting 66 lbs. of insertion force. In one embodiment, the handle 306 is 1.7 in. long and provides a 3 to 1 mechanical advantage, thereby enabling a PCB (not shown) requiring 132 lbs. of insertion force to be inserted by applying 22 lbs. of force to each of the two ejectors 302 and 314.

Although an exemplary embodiment of the invention has been disclosed, it will be apparent to those skilled in the art that various changes and modifications can be made which will achieve some of the advantages of the invention without departing from the spirit and scope of the invention. For example, it will be obvious to those reasonably skilled in the art that, although the description was directed to a particular hardware configuration, other hardware configurations could be used in the same manner as that described. Other aspects, such as conventional variations in the specific sizes of components recited in the specification to achieve a particular function, as well as other modifications to the inventive concept are intended to be covered by the appended claims.

What is claimed is:

1. A printed circuit board ejector system for use with a printed circuit board that is inserted into, and removed from, a card cage, the system comprising:
an electrically-conductive faceplate that has a length and is constructed to withstand forces required to insert and remove the printed circuit board from the card cage without bending or breaking;
means for fastening the faceplate to one edge of the printed circuit board so that the faceplate extends perpendicular to the printed circuit board and along the one edge and has an outer surface that faces away from the printed circuit board;
at least one ejector lever that engages the card cage to provide insertion and removal forces; and
means for fastening the ejector lever to the outer surface of the faceplate.

2. The system of claim 1 wherein the faceplate is constructed with a stiffening rib extending along the length.

3. The system of claim 1 wherein the faceplate has a U-shaped cross section.

4. The system of claim 1 wherein the means for fastening the faceplate comprises a bracket connected to the faceplate.

5. The system of claim 4 wherein the bracket is connected to a rib that extends along the length.

6. The system of claim 5 wherein the bracket is offset from the rib.

7. The system of claim 1 wherein the means for fastening the ejector lever comprises a screw that passes through the faceplate and threads into the ejector lever.

8. The system of claim 1 wherein the means for fastening the ejector lever comprises welding the ejector lever to the faceplate.

9. The system of claim 1 wherein the means for fastening the ejector lever comprises adhesive.

10. A method for constructing a printed circuit board ejector system for use with a printed circuit board that is inserted into, and removed from, a card cage, the system comprising:
(a) constructing an electrically-conductive faceplate with a length and to withstand forces required to insert and remove the printed circuit board from the card cage without bending or breaking;
(b) fastening the faceplate to one edge of the printed circuit board so that the faceplate extends perpendicular to the printed circuit board and along the one edge and has an outer surface that faces away from the printed circuit board;
(c) forming at least one ejector lever that engages the card cage to provide insertion and removal forces; and
(d) fastening the ejector lever to the outer surface of the faceplate.

11. The method of claim 10 wherein step (a) comprises constructing the faceplate with a stiffening rib extending along the length.

12. The method of claim 10 wherein step (a) comprises constructing the faceplate with a U-shaped cross section.

13. The method of claim 10 wherein step (b) comprises fastening the faceplate with a bracket connected to the faceplate.

14. The method of claim 13 wherein the bracket is connected to a rib that extends along the length.

15. The method of claim 14 wherein the bracket is offset from the rib.

16. The method of claim 10 wherein step (d) comprises fastening the ejector lever to the faceplate with a screw that passes through the faceplate and threads into the ejector lever.

17. The method of claim 10 wherein the means for fastening the ejector lever comprises welding the ejector lever to the faceplate.

18. The method of claim 10 wherein step (d) comprises fastening the ejector lever to the faceplate with adhesive.

19. A printed circuit board ejector system for use with a printed circuit board that is inserted into, and removed from, a card cage, the system comprising:
an electrically-conductive faceplate that has a length and a U-shaped cross-section having a first rib extending along the length and a second rib extending along the length;
a bracket that is attached to the first rib and extends along the length and at least one bolt that passes through one edge of the printed circuit board and the bracket so that the faceplate extends perpendicular to the printed circuit board and along the one edge and has an outer surface that faces away from the printed circuit board;
at least one ejector lever that engages the card cage to provide insertion and removal forces; and
a least one screw that passes through the faceplate and threads into the ejector lever to fasten the ejector lever to the outer surface of the faceplate.

20. The system of claim 19 wherein the bracket is offset from the first rib.
